(19) United States
(12) Patent Application Publication
(10) Pub. No.: US 2020/0163229 A1
(43) Pub. Date: May 21, 2020

(54) CIRCUIT BOARD AND METHOD OF MAKING CIRCUIT BOARD

(71) Applicant: Qi Ding Technology Qinhuangdao Co., Ltd., Qinhuangdao (CN)

(72) Inventors: SHIH-FU HUANG, Tayuan (TW); YU-CHENG HUANG, Taoyuan (TW)

(21) Appl. No.: 16/378,061

(22) Filed: Apr. 8, 2019

(30) Foreign Application Priority Data
Nov. 15, 2018 (CN) 201811361685.7

(51) Int. Cl. H05K 3/42; H05K 1/11; H05K 3/10

(52) U.S. Cl. CPC H05K 3/428; H05K 1/113; H05K 3/108; H05K 3/0026; H05K 2201/09636; H05K 2201/0195; H05K 2201/096

(57) ABSTRACT

A circuit board includes a first conductive circuit layer, a cover layer, and a second conductive circuit layer. The cover layer includes an adhesive layer and a base film. The first conductive circuit layer is embedded within the adhesive layer. One side of the first conductive circuit layer is revealed from the adhesive layer. The second conductive circuit layer is located on a side of the base film facing away from the adhesive layer. The cover layer defines a first through hole and a second through hole passing through the cover layer. A diameter of the first through hole is greater than a diameter of the second through hole. The first through hole is filled with a copper post adjacent to the first conductive circuit layer and an electroplating layer adjacent to the second conductive circuit layer. The second through hole is filled with the electroplating layer.

### FIELD

The subject matter herein generally relates to circuit boards, and more particularly to a circuit board and a method of making the circuit board.

### BACKGROUND

When manufacturing a multi-layer circuit board, a conductive hole generally must be defined and copper is plated within the conductive hole to fill upper and lower layers of the circuit board. The amount of copper plating required for filling the conductive holes varies according to different sizes of the conductive holes, and the conductive holes are generally filled together in one electroplating process, which results in the conductive holes of different sizes being filled to different levels, which affects a quality of the circuit board. In addition, larger conductive holes require longer times and more energy to be laser processed.

### BRIEF DESCRIPTION OF THE DRAWINGS

Implementations of the present disclosure will now be described, by way of embodiments, with reference to the attached figures.

FIG. 1 is a cross-sectional view showing a first photoresist pattern layer formed on a carrier board according to an embodiment.

FIG. 2 is a cross-sectional view showing a first conductive circuit layer formed on the carrier after forming the first photoresist pattern layer.

FIG. 3 is a cross-sectional view showing formation of a second photoresist pattern layer on the carrier board after forming the first conductive circuit layer.

FIG. 4 is a cross-sectional view showing a copper post formed on the carrier board after the second photoresist pattern layer is formed.

FIG. 5 is a cross-sectional view of the copper post of FIG. 4 after being smoothed.

FIG. 6 is a cross-sectional view of the carrier board of FIG. 5 having the first photoresist pattern layer and the second photoresist pattern layer removed.

FIG. 7 is a cross-sectional view showing a cover layer on the first conductive circuit layer and the copper post.

FIG. 8 is a cross-sectional view of the cover layer of FIG. 7 after defining holes.

FIG. 9 is a cross-sectional view of the cover layer of FIG. 8 after forming a third photoresist pattern layer.

FIG. 10 is a cross-sectional view showing the second conductive circuit layer and a copper plating layer formed on the cover layer.

FIG. 11 is a cross-sectional view showing the first conductive circuit layer separated from the carrier board.

FIG. 12 is a cross-sectional view showing the first conductive circuit layer after etching to remove a seed layer.

FIG. 13 is a cross-sectional view showing formation of a solder resist layer on surfaces of the first conductive circuit layer and the second conductive circuit layer.

FIG. 14 is a cross-sectional view of a circuit board according to an embodiment.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

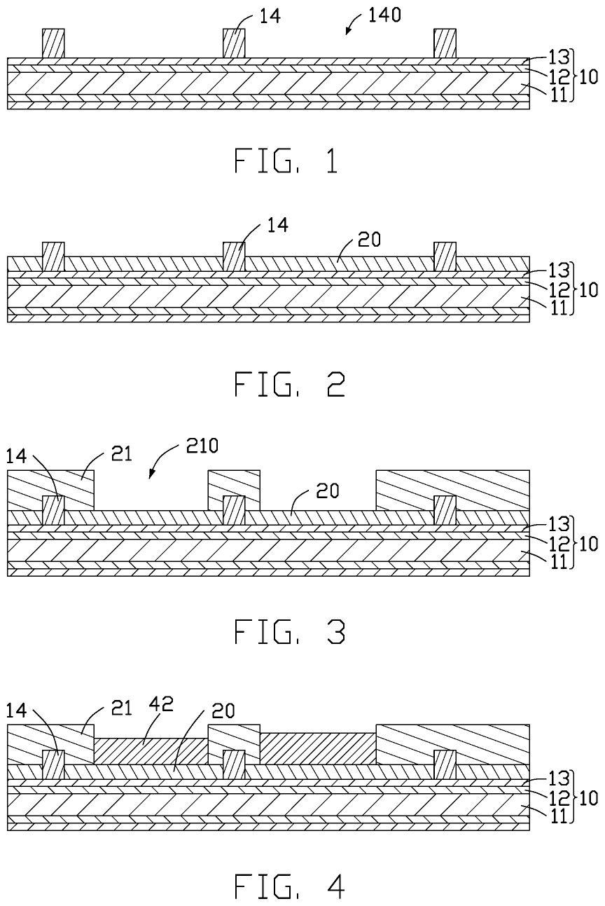

FIGS. 1-14 show a circuit board manufacturing method according to an embodiment.

In a first step, as shown in FIG. 1 and FIG. 2, a carrier board 10 is provided. The carrier board 10 includes a seed layer 13, and a first conductive circuit layer 20 is electroplated on a surface of the seed layer 13.

In one embodiment, the carrier board 10 includes a base material layer 11, a release film 12 provided on the base material layer 11, and the seed layer 13 formed on a surface of the release film 12.

The base material layer 11 may be selected from, but is not limited to, polyimide (PI), liquid crystal polymer (LCP), polyethylene terephthalate (PET), and polyethylene naphthalate (PEN).

The release film 12 facilitates separation of the carrier board 10 from the seed layer 13 in a subsequent step.

Referring to FIG. 1 and FIG. 2, the first conductive circuit layer 20 is formed by the following steps.

Referring to FIG. 1, a dry film is laminated on a surface of the seed layer 13, and the dry film is exposed to form a first photoresist pattern layer 14. Exposed portions of the first photoresist pattern layer 14 form first gaps 140.

Referring to FIG. 2, the first conductive circuit layer 20 is formed by electroplating the surface of the seed layer 13 within the first gaps 140.

In a second step, referring to FIG. 3 and FIG. 4, at least one copper post 42 is formed on a surface of the first conductive circuit layer 20, and the at least one copper post 42 is located corresponding to a predetermined first conductive hole 303 (shown in FIG. 14).

Referring to FIGS. 3 and 4, the at least one copper post 42 is formed by the following steps.

Referring to FIG. 3, a dry film is pressed on a surface of the first conductive circuit layer 20 and the first photoresist pattern layer 14, and the dry film is exposed to form a second photoresist pattern layer 21. Exposed portions of the second photoresist pattern layer 21 form second gaps 210, and the second gaps 210 are located corresponding to the predetermined first conductive holes 303.

Referring to FIG. 4, the copper posts 42 are formed by electroplating the surface of the first conductive circuit layer 20 within the second gaps 210.

In one embodiment, the copper post 42 has a diameter ranging from 100 micrometers to 1000 micrometers. The ratio between the diameter of the copper post 42 at an end of the copper post 42 adjacent to the first conductive circuit layer 20 and the diameter of an opposite end of the copper post 42 is 95% to 105%.

In a third step, referring to FIG. 5, at least one of the copper posts 42 is smoothed.

In one embodiment, at least one of the copper posts 42 is polished and smoothed to ensure uniformity of subsequent plating processes. In other embodiments, this step may be omitted.

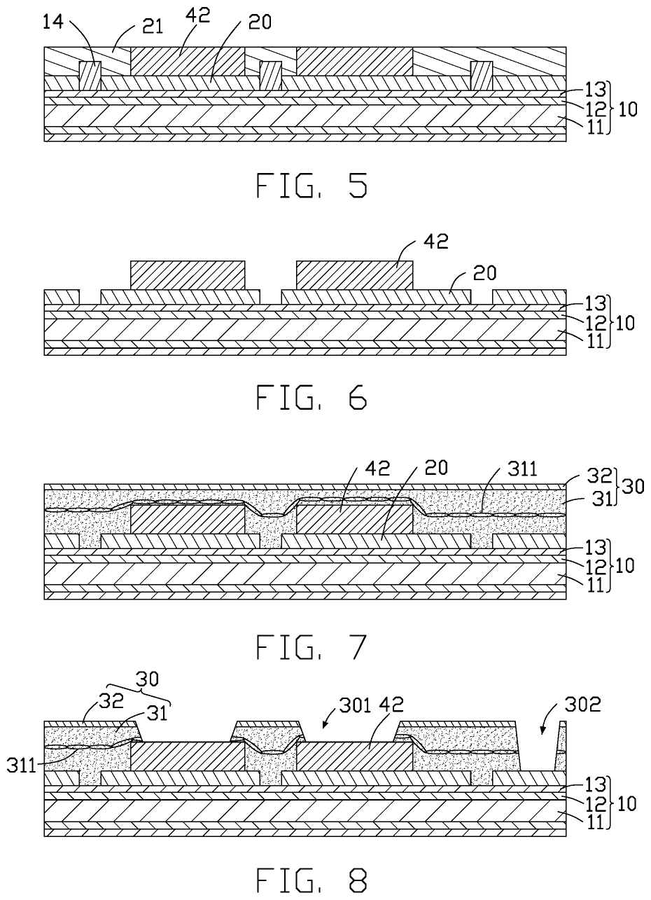

In a fourth step, referring to FIG. 6, the first photoresist pattern layer 14 and the second photoresist pattern layer 21 are removed.

In other embodiments, the first photoresist pattern layer 14 is removed after the first conductive circuit layer 20 is formed, and the second photoresist pattern layer 21 is removed after the at least one copper post 42 is formed.

In a fifth step, referring to FIG. 7, a cover layer 30 is provided and attached to the first conductive circuit layer 20 and the copper posts 42.

The cover layer 30 includes an adhesive layer 31 and a base film 32. The base film 32 is mounted on the first conductive circuit layer 20 and the copper posts 42 through the adhesive layer 31.

The base film 32 may be selected from, but is not limited to, polyimide (PI), liquid crystal polymer (LCP), polyethylene terephthalate (PET), and polyethylene naphthalate (PEN).

In one embodiment, a glass fiber cloth 311 is disposed in the adhesive layer 31 to increase an overall hardness of the circuit board, but is not limited thereto.

In a sixth step, referring to FIG. 8, at least one first through hole 301 and at least one second through hole 302 are defined in the cover layer 30. The at least one first through hole 301 is aligned with the at least one copper posts 42, and the at least one second through hole 302 is aligned with the first conductive circuit layer 20. The diameter of the first through hole 301 is greater than the diameter of the second through hole 302.

Since the first through hole 301 is aligned with the copper post 42, the first through hole 301 has a lower depth than the second through hole 302. A portion of the glass fiber cloth 311 located above the copper post 42 is removed by laser processing.

In one embodiment, the first through hole 301 has a diameter ranging from 100 micrometers to 1000 micrometers. The ratio between the diameter of an end of the first through hole 301 adjacent to the first conductive circuit layer 20 and the diameter of an opposite end of the first through hole 301 is 60% to 90%.

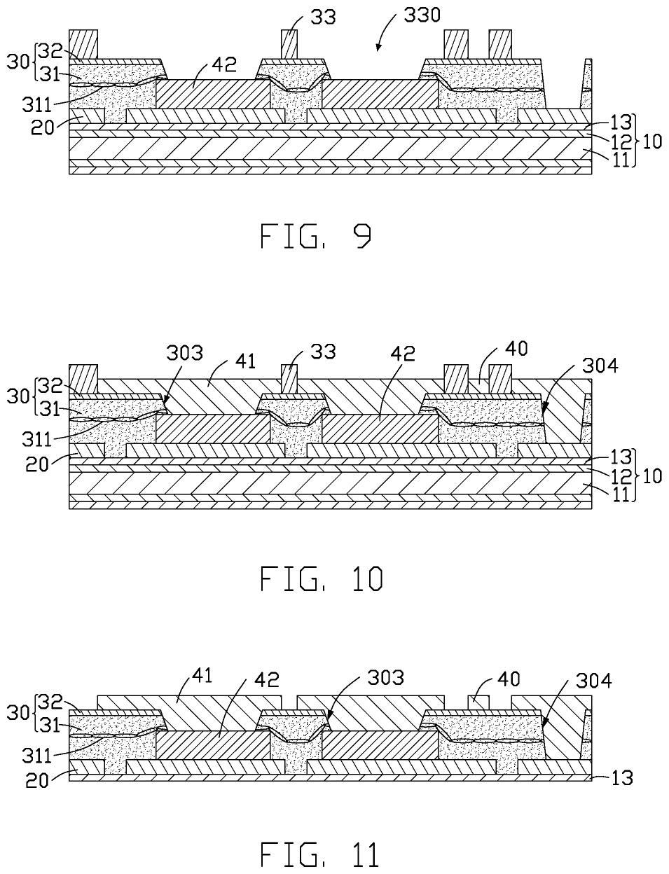

In a seventh step, referring to FIG. 9 and FIG. 10, a second conductive circuit layer 40 is electroplated on a surface of the cover layer 30, and a copper plating layer 41 is electroplated within the first through hole 301 and the second through hole 302 to form a first conductive hole 303 and a second conductive hole 304, respectively.

Referring to FIG. 9 and FIG. 10, the second conductive circuit layer 40, the first conductive hole 303, and the second conductive hole 304 are formed by the following steps.

Referring to FIG. 9, a dry film is pressed on a surface of the cover layer 30 and the copper posts 42, and the dry film is exposed to form a third photoresist pattern layer 33. Exposed portions of the third photoresist pattern layer 33 form third gaps 330.

Referring to FIG. 10, the third gaps 330 are electroplated to form a second conductive circuit layer 40 and a copper plating layer 41. The second conductive circuit layer 40 is formed on a surface of the cover layer 30, and the copper plating layer 41 is formed within the first conductive hole 303 and the second conductive hole 304.

The diameter of the first through hole 301 is larger than the diameter of the second through hole 302. The depth of the first through hole 301 is less than the depth of the second through hole 302. After electroplating, a surface of the copper plating layer 41 in the first through hole 301 is substantially aligned with a surface of the copper plating layer 41 in the second through hole 302.

In an eighth step, referring to FIG. 11, the base material layer 11 and the release film 12 of the carrier board 10 are removed.

The base material layer 11 is separated from the first conductive circuit layer 20 by tearing off the release film 12, thereby leaving behind the seed layer 13 coupled to the first conductive circuit layer 20.

In a ninth step, referring to FIG. 12, the seed layer 13 is etched away.

The seed layer 13 is etched away to allow the first conductive circuit layer 20 to couple to other components. In other embodiments, this step may be omitted.

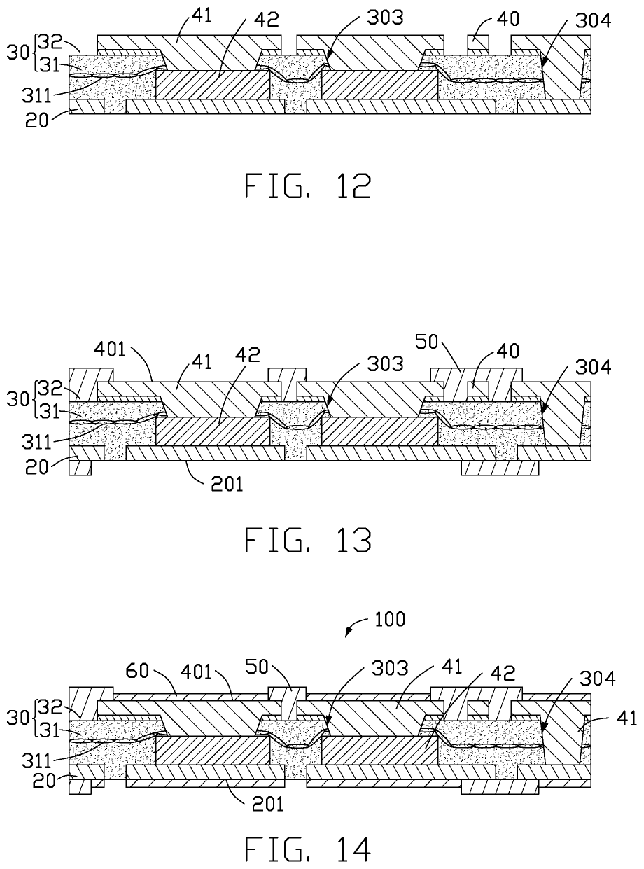

In a tenth step, referring to FIG. 13, a solder resist layer 50 is formed on a surface of the first conductive circuit layer 20 and of the second conductive circuit layer 40. A portion of the first conductive circuit layer 20 not covered by the solder resist layer 50 forms a first electrical contact pad 201, and a portion of the second conductive circuit layer 40 not covered by the solder resist layer 50 forms a second electrical contact pad 401.

In one embodiment, the solder resist layer 50 is formed by using a liquid photosensitive solder resist ink, and the solder resist layer 50 is formed by printing the liquid photosensitive solder resist ink on surface regions of the first conductive circuit layer 20 and the second conductive circuit layer 40 and on regions therebetween, pre-curing a surface of the liquid photosensitive solder resist ink, selectively UV exposing portions of the liquid photosensitive solder resist ink to cause a cross-linking reaction to occur in the portions of the liquid photosensitive solder resist ink, exposing and removing portions of the liquid photosensitive solder resist ink not cross-linked to reveal the first electrical contact pad 201 and the second electrical contact pad 401, and curing the liquid photosensitive solder resist ink by heating to form the solder resist layer 50.

In other embodiments, the solder resist layer 50 may be formed by coating.

In an eleventh step, referring to FIG. 14, the first electrical contact pad 201 and the second electrical contact pad 401 are surface-treated to form a surface treatment layer 60 to protect the first electrical contact pad 201 and the second electrical contact pad 401.

In one embodiment, the surface treatment layer 60 is formed by chemical or physical methods. The material of the surface treatment layer 60 can be selected from at least one of graphite, gold, nickel-gold, nickel-palladium-gold, tin, silver, and an organic solder resist film. In other embodiments, the surface treatment layer 60 may be omitted.

In the method as described above, the at least one copper post 42 is formed on the surface of the first conductive circuit layer 20, and then the first through hole 301 is formed corresponding in position to the copper post 42 so that the depth of the first through hole 301 is less than the depth of the second through hole 302. Since the diameter of the first through hole 301 is larger than the diameter of the second through hole 302, the time of electroplating the first through hole 301 is substantially equal to the time of electroplating the second through hole 302, and the surface of the copper plating layer 41 in the first through hole 301 is substantially flush with the surface of the copper plating layer 41 in the second through hole 302. Since the first through hole 301 has a reduced depth, a required time of laser processing the first through hole 301 can be reduced, thereby increasing efficiency and reducing an amount of heat generated by laser processing.

Referring to FIG. 14, a circuit board 100 includes a first conductive circuit layer 20, a cover layer 30, and a second conductive circuit layer 40. The cover layer 30 includes an adhesive layer 31 and a base film 32. The first conductive circuit layer 20 is embedded within the adhesive layer 31, and one side of the first conductive circuit layer 20 is revealed from the adhesive layer 31. The second conductive circuit layer 40 is arranged on a side of the base film 32 facing away from the adhesive layer 31. The cover layer 30 defines a first through hole 301 and a second through hole 302. The diameter of the first through hole 301 is larger than the diameter of the second through hole 302. The first through hole 301 is filled with a copper post 42 adjacent to the first conductive circuit layer 20 and a copper plating layer 41 adjacent to the second conductive circuit layer 40. The second through hole 302 is filled with the copper plating layer 41.

A solder resist layer 50 is formed on a surface of the first conductive circuit layer 20 and the second conductive circuit layer 40. A portion of the first conductive circuit layer 20 not covered by the solder resist layer 50 forms a first electrical contact pad 201, and a portion of the second conductive circuit layer 40 not covered by the solder resist layer 50 forms a second electrical contact pad 401.

A surface of the first electrical contact pad 201 and of the second electrical contact pad 401 forms a surface treatment layer 60. The material of the surface treatment layer 60 may be selected from one or a combination of graphite, gold, nickel-gold, nickel-palladium-gold, tin, silver, and an organic solder resist film.

The copper post 42 has a diameter ranging from 100 micrometers to 1000 micrometers. The ratio between the diameter of an end of the copper post 42 adjacent to the first conductive circuit layer 20 and the diameter of an opposite end of the copper post 42 is 95% to 105%.

The first through hole 301 has a diameter ranging from 100 micrometers to 1000 micrometers. The ratio between the diameter of an end of the first through hole 301 adjacent to the first conductive circuit layer 20 and the diameter of an opposite end of the first through hole 301 is 60% to 90%.

A glass fiber cloth 311 is arranged within the adhesive layer 31 to increase an overall hardness of the circuit board 100.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. A circuit board manufacturing method comprises:
providing a carrier plate, the carrier plate comprising a seed layer, and electroplating a surface of the seed layer to form a first conductive circuit layer;
forming at least one copper post on a surface of the first conductive circuit layer, the at least one copper post being located at a predetermined first conductive hole;
providing a cover layer and attaching the cover layer to the first conductive circuit layer and the at least one copper post;
defining at least one first through hole and at least one second through hole in the cover layer, wherein the at least one first through hole is aligned with the at least one copper post, the at least one second through hole is aligned with the first conductive circuit layer, a diameter of the first through hole is greater than a diameter of the second through hole, and a depth of the first through hole is less than a depth of the second through hole;
electroplating a surface of the cover layer to form a second conductive circuit layer and electroplating the first through hole and the second through hole to form a copper plating layer, so that the first through hole and the second through hole respectively form a first conductive hole and a second conductive hole; and
removing the carrier plate.

2. The method of claim 1, wherein after the carrier plate is removed, the method further comprises:
forming a solder resist layer on a surface of the first conductive circuit layer and the second conductive circuit layer, so that a portion of the first conductive circuit layer not covered by the solder resist layer forms a first electrical contact pad, and a portion of the second conductive circuit layer not covered by the solder resist layer forms a second electrical contact pad.

3. The method of claim 2, wherein after the solder resist layer is formed, the method further comprises:
surface treating the first electrical contact pad and the second electrical contact pad to form a surface treatment layer.

4. The method of claim 1, wherein after the at least one copper post is formed and before the cover layer is provided, the method further comprises:
smoothing the at least one copper post.

5. The method of claim 1, wherein after the carrier board is removed, the method further comprises:
removing the seed layer by etching.

6. A circuit board comprising:
a first conductive circuit layer;
a cover layer comprising an adhesive layer and a base film;
a second conductive circuit layer; wherein:
the first conductive circuit layer is embedded within the adhesive layer;
one side of the first conductive circuit layer is revealed from the adhesive layer;
the second conductive circuit layer is located on a side of the base film facing away from the adhesive layer;
the cover layer defines a first through hole and a second through hole passing through the cover layer;
a diameter of the first through hole is greater than a diameter of the second through hole;
the first through hole is filled with a copper post adjacent to the first conductive circuit layer and an electroplating layer adjacent to the second conductive circuit layer;
the second through hole is filled with the electroplating layer.

7. The circuit board of claim 6, wherein;
a surface of the first conductive circuit layer and of the second conductive circuit layer form a solder resist layer;
a portion of the first conductive circuit layer not covered by the solder resist layer forms a first electrical contact pad; and
a portion of the second conductive circuit layer not covered by the solder resist layer forms a second electrical contact pad.

8. The circuit board of claim 7, wherein:
a surface of the first electrical contact pad and of the second electrical contact pad form a surface treatment layer.

9. The circuit board of claim 6, wherein:
a diameter of the copper post is 100-1000 micrometers;
a ratio of a diameter of an end of the copper post adjacent to the first conductive circuit layer and an opposite end of the copper post is 95%-105%.

10. The circuit board of claim 6, wherein:
the adhesive layer comprises a glass fiber cloth.
